(19) United States
(12) Patent Application Publication
(10) Pub. No.: US 2020/0341066 A1
(43) Pub. Date: Oct. 29, 2020

(54) USER INTERFACE FOR A BATTERY TESTER

(71) Applicant: CPS Technology Holdings LLC, New York, NY (US)

(72) Inventors: Clare Frigo, Pewaukee, WI (US); Dale Gospodarek, Kenosha, WI (US); Julie Roberts, Cedarburg, WI (US); Itziar Frias, Milwaukee, WI (US); Kenneth B. Cherry, Lawrenceville, GA (US); David Scheck, Schaumburg, IL (US); Andrew J. Salo, III, Chicago, IL (US); Sarah Spang, Chicago, IL (US); Ryan Sweeney, Chicago, IL (US)

(21) Appl. No.: 16/758,349

(22) PCT Filed: Oct. 23, 2018
(86) PCT No.: PCT/US2018/057140

§ 371 Date: Apr. 22, 2020

Related U.S. Application Data
(60) Provisional application No. 62/575,960, filed on Oct. 23, 2017.
(60) Provisional application No. 62/578,974, filed on Oct. 30, 2017.

(51) Int. Cl. G01R 31/36; G01R 31/378; G01R 31/392; G06F 3/0484; G06F 3/041; G06F 3/0488

(52) U.S. Cl. CPC G01R 31/3646; G01R 31/378; G01R 31/3647; G06F 3/0488; G06F 3/04842; G06F 3/0412; G01R 31/392

(57) ABSTRACT

Disclosed is a battery tester comprising a computing device and a screen, the computing device being configured to display on the screen a user interface for improved battery testing; the user interface comprising a series of interfaces: a first interface comprising a plurality of icons, each of the plurality of icons corresponding to at least one of a test condition or a tester functionality; a testing interface comprising a number of instructions which update based on a user interaction with the vehicle, and wherein selection of an icon in the first interface corresponding to a test condition displays the testing interface; and a results interface, having a three-stage top navigation and summary, the three-stage top navigation for reporting battery health metrics, wherein completion of the testing interface displays a results interface.

### CROSS-REFERENCE TO RELATED APPLICATIONS

This application claims priority to U.S. Provisional Patent Application No. 62/575,960 filed Oct. 23, 2017 and 62/578,974 filed Oct. 30, 2017, the entirety of both of which are incorporated herein by reference.

### FIELD

This application relates to battery testers. More specifically, this application relates to a user interface for a battery tester.

### BACKGROUND

A battery tester may be used in a number of scenarios. It may be used on a battery installed in a vehicle, a battery removed from a vehicle, or a new battery.

Known battery testers have two cables: a positive and a negative cable, which are attached to the battery's positive and negative terminal. The battery tester uses these connected cables to perform a series of tests on the vehicle. The tests are then used to produce a report, typically regarding battery state of charge and/or health. The battery tester is typically operated by a technician.

Known testers have user interfaces with a number of disadvantages. For example, known testers may have user interfaces that are difficult to navigate when connected to a battery. Known testers may have user interfaces that only work with large, horizontal screens, requiring cumbersome tester positioning. Other known testers may have physical button-based navigation with small mono-color screens; others may require printouts to display testing results.

Known testers may therefore have user interfaces that are difficult to navigate and obtain results. What is needed is a battery tester user interface that remedies these and other deficiencies.

### SUMMARY OF THE INVENTION

Disclosed is a battery tester user interface that seeks to remedy the above and other deficiencies.

In various embodiments of the invention, the battery tester user interface may be vertically-oriented (i.e. portrait orientation). The orientation may facilitate ease of operation of the battery tester by a technician by allowing for one-handed interaction with the interface. This may allow for improved ability to perform the testing—in other words, the technician may hold the device in one hand and perform physical testing with the other. In addition, the user interface may be configured for display on a touch screen, allowing for ease of access throughout testing.

The battery tester user interface according to various embodiments of the invention may include improved navigation features. For example, the interface may allow for elements to be displayed in a single, more easily-navigable screen during testing. As a further non-limiting example, the user interface may be vertically oriented to allow for ease of navigation while a tester is held.

As another non-limiting example, the interface may allow for single-touch access to multiple testing aspects. The user interface may allow for easily navigable display of a large amount of information. For example, the user interface may comprise a three-stage top navigation for displaying testing results, which may allow for quick and easy navigation to relevant battery health and battery test data.

Disclosed is a battery tester comprising a computing device and a screen, the computing device being configured to display on the screen a user interface for improved battery testing, the user interface comprising a series of interfaces: a first interface comprising a plurality of icons, each of the plurality of icons corresponding to at least one of a test condition or a tester functionality; a testing interface comprising a number of instructions which update based on a user interaction with the vehicle, and wherein selection of an icon in the first interface corresponding to a test condition displays the testing interface; and a results interface, having a three-stage top navigation and summary, the three-stage top navigation for reporting battery health metrics, wherein completion of the testing interface displays a results interface. Further disclosed is a battery tester wherein the one or more of the top navigation comprises a cranking result or a charging result. Further disclosed is a battery tester wherein selection of one or more of the three-stage navigation presents a battery replacement recommendation. Further disclosed is a battery tester wherein selection of one of the three-stage navigation provides a testing results summary interface. Further disclosed is a battery tester wherein viewing of the testing results summary interface may be achieved by scrolling downward on the tester user interface. Further disclosed is a battery tester comprising a vehicle record interface, the vehicle record interface having a plurality of fields for inputting vehicle information, wherein the interface may be populated by a user or tester-obtained data. Further disclosed is a battery tester wherein the battery tester is sized to be held one-handed.

Disclosed is a method for improved battery health data capture and display, the method comprising: holding a battery tester, the battery tester having a screen displaying a user interface; selecting one of a plurality of icons displayed on the user interface corresponding to a test condition to begin a test; displaying on the user interface a testing interface which dynamically updates based on the completion of one or more testing steps; upon completion of one or more tests, displaying on the user interface a results interface having a three-stage navigation and health summary, the three-stage top navigation corresponding to different battery health information; selecting on the user interface one or more of the three-stage top navigation to display a results summary and recommendation regarding battery health. Further disclosed is a method further comprising populating on the user interface a vehicle information interface, the vehicle information interface optionally being populated by manual entry. Further disclosed is a method wherein the battery tester is sized to be held in one hand. Further disclosed is a method wherein the user interface is vertically-oriented. Further disclosed is a method wherein the battery tester screen is a touchscreen. Further disclosed is a method wherein one of the three-stage top navigation comprises a cranking result. Further disclosed is a method wherein selection of one or more of the three-stage navigation presents a battery replacement recommendation. Further disclosed is a method wherein selection of one of the three-stage navigation provides a testing results summary interface.

Disclosed herein is a method for displaying battery health information on a graphical user interface, the method comprising: providing a touchscreen on a battery tester, the touchscreen displaying a user interface; displaying on the user interface a testing interface which dynamically updates with testing instructions based on the completion of one or more testing steps; upon completion of one or more tests, displaying on the user interface a results interface having a three-stage navigation and health summary, the three-stage top navigation corresponding to different battery health metrics; selecting on the user interface one or more of the three-stage top navigation to display a testing results summary and recommendation regarding battery health. Further disclosed is a method wherein the battery tester is sized to be held in one hand. Further disclosed is a method wherein the user interface is vertically-oriented. Further disclosed is a method wherein one of the three-stage top navigation comprises a cranking result.

In summary, the disclosed battery tester user interface and method may allow for improved ease of operation and display of information over known battery testers. These and other advantages are disclosed further herein.

### BRIEF DESCRIPTION OF THE FIGURES

FIG. 1 shows a battery tester having a user interface, according to one or more embodiments.

FIG. 2 shows a battery tester having a user interface being held by a user, according to one or more embodiments.

FIG. 3 shows another embodiment of a battery tester having a user interface, according to one or more embodiments.

FIG. 4 shows a second view of a battery tester of FIG. 3 having the user interface, according to one or more embodiments.

FIGS. 5A-5C show a battery tester user interface display showing an unlocking interface, according to one or more embodiments.

FIG. 6 shows a battery tester user interface display showing a navigation interface, according to one or more embodiments.

FIG. 7 shows a battery tester user interface display showing a vehicle information interface, according to one or more embodiments.

FIGS. 8A-8B show a battery tester user interface display showing a vehicle information interface, according to one or more embodiments.

FIGS. 9A-9B show a battery tester user interface display showing a battery information interface, according to one or more embodiments.

FIG. 10 shows a battery tester user interface display showing a testing instruction interface, according to one or more embodiments.

FIG. 11 shows a battery tester user interface display showing a cranking results interface, according to one or more embodiments.

FIG. 12 shows a battery tester user interface display showing a charging results interface, according to one or more embodiments.

FIG. 13 shows a battery tester user interface display showing a testing results interface, according to one or more embodiments.

FIG. 14 shows a battery tester user interface display showing another view of a testing results interface, according to one or more embodiments.

FIGS. 15A-B show a battery tester user interface display showing another view of a testing results interface, according to one or more embodiments.

FIG. 16 shows a battery tester user interface display another view of a testing results interface, according to one or more embodiments.

FIGS. 17A-B show a battery tester user interface display, according to one or more embodiments.

FIGS. 18A-D show a battery tester user interface display, according to one or more embodiments.

FIG. 19 shows a front and back of a battery tester having a user interface display according to one or more embodiments.

FIG. 20 shows a battery tester user interface method according to one or more embodiments.

FIGS. 21A-21B show a battery tester user interface display including a settings interface, according to one or more embodiments.

It should be understood that the drawings are not necessarily to scale. In certain instances, details that are not necessary to the understanding to the invention or render other details difficult to perceive may have been omitted. It should be understood, of course, that the invention is not necessarily limited to the particular embodiments illustrated herein.

### DESCRIPTION OF THE INVENTION

Turning to the Figures, a battery tester user interface according to various examples of embodiments is disclosed. Also disclosed is a method of operation and navigation facilitated by the battery tester user interface according to various examples of embodiments.

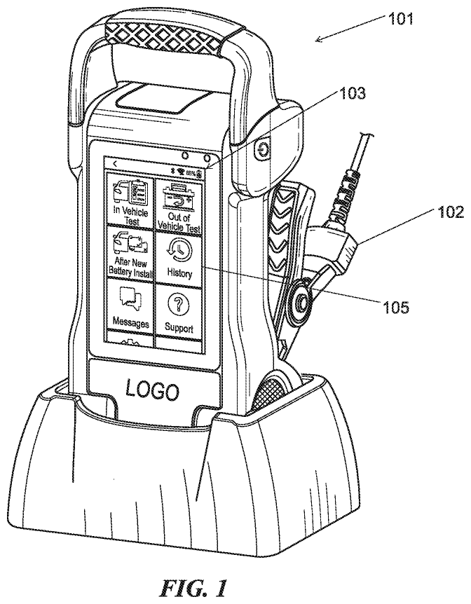

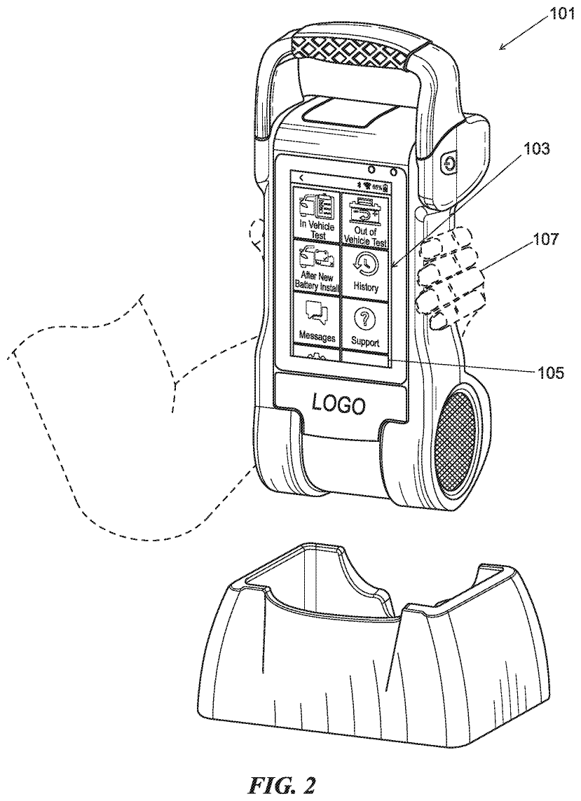

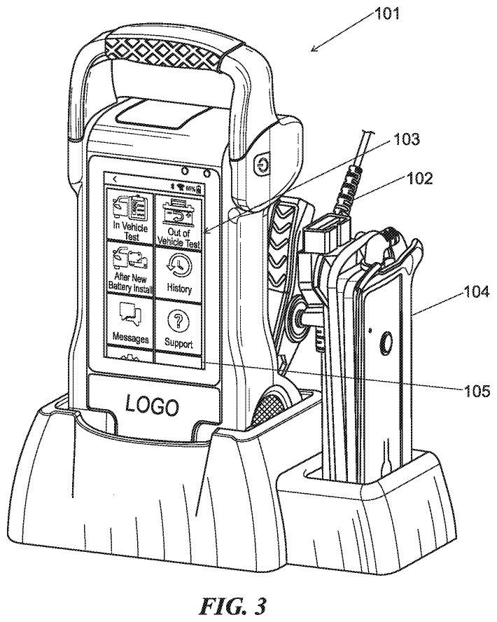

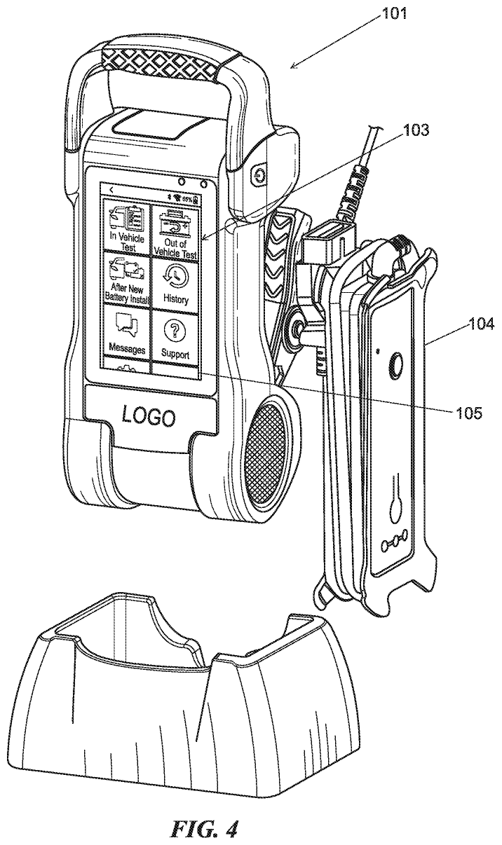

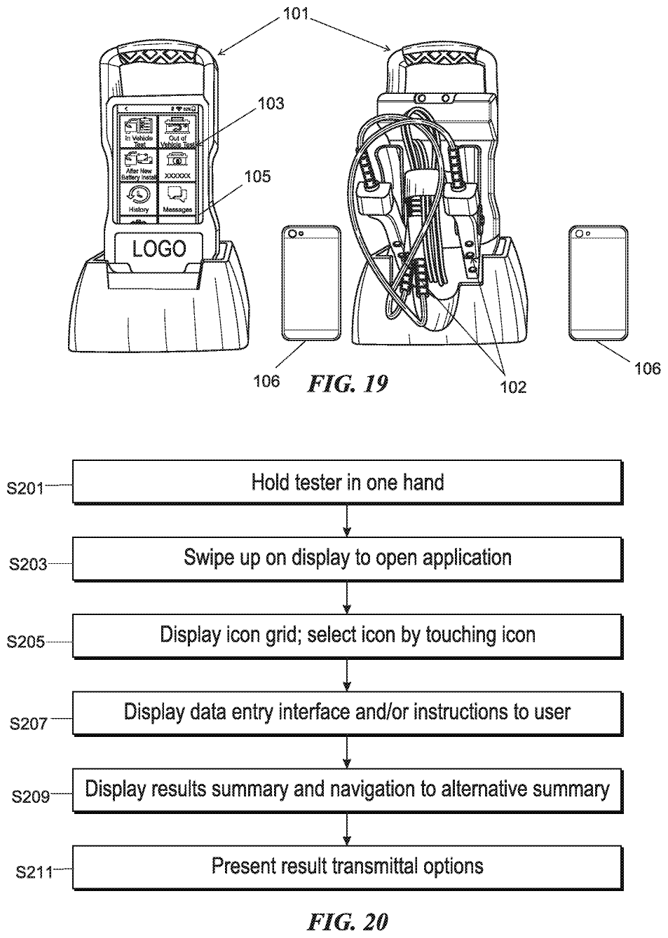

In FIGS. 1-4, a battery tester 101 having a user interface 105 according to various examples of embodiments is disclosed. The battery tester 101 may be sized, for example, to be gripped by a single hand 107 (see FIG. 2). The battery tester 101 may be held, for example, such that a thumb could grip one side and fingers the other, with the back of the hand cradling the back of the tester and leaving the front display 103 (which may comprise a touchscreen) featuring the user interface 105 exposed. An example of a hand 107 holding a battery tester 101 according to various examples of embodiments can be seen in FIG. 2. As can be seen in FIGS. 1 and 19, the tester 101 may likewise comprise one or more tester cables 102 (for example, two cables for positive and negative connection). In addition, as shown in FIG. 3 and FIG. 4, the tester may have one or more holder(s) and one or more peripheral device(s) 104.

As can be readily ascertained, the battery tester 101 may feature a screen or display 103 on a front of the tester. The display 103 may be a touch-sensitive screen. The front of the battery tester 101 may not have traditional, tactile “buttons.” Instead, testing according to one or more examples of embodiments is navigated using the display 103 featuring the user interface 105. However, in alternative embodiments, the front of the tester 101 may comprise one or more tactile buttons. As shown in one or more illustrated embodiments, the screen 103 is vertically oriented on the battery tester 101. The vertical orientation may allow the battery tester to advantageously feature more area for the screen while allowing the user to hold the tester. The vertically-oriented user interface may allow for ease of operation of the battery tester while held in a technician's hand. For example, the battery tester 101may be held and operated via the user interface 105 while accessing a battery for testing (for example, a battery for use with a vehicle, the battery being accessed for testing in various embodiments inside or outside of the vehicle).

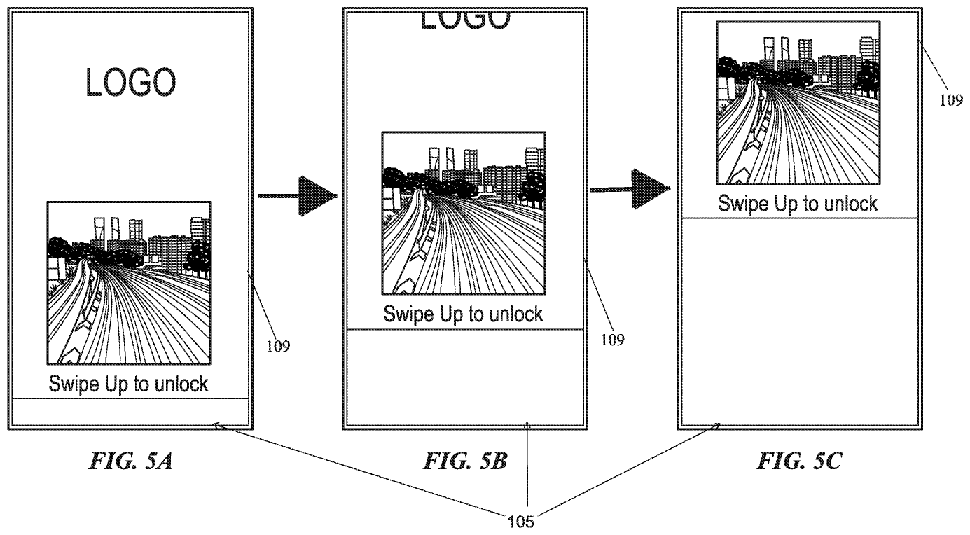

In FIGS. 5A-5C, a first user interface 105 display screen is shown. The user interfaces shown herein may be understood to show a display of a screen 103 having a user interface 105 as it is oriented on a battery tester 101 (i.e. in a vertical orientation on a vertical screen provided on the battery tester). Alternative gestures, such as side swipe or tapping, are contemplated as within the scope of this disclosure.

Moving from FIG. 5A to FIG. 5B to FIG. 5C, the figures show the user interface 105 having an unlocking interface 109 which changes as the result of a motion of swiping towards a top of the page to launch or unlock the device. In various embodiments, the user may drag his or her finger from a bottom portion of the interface screen toward an upper or top portion of the screen. By interacting with the screen 103 of the battery tester 101 in this way, access to tester functionality, for example, battery testing may begin.

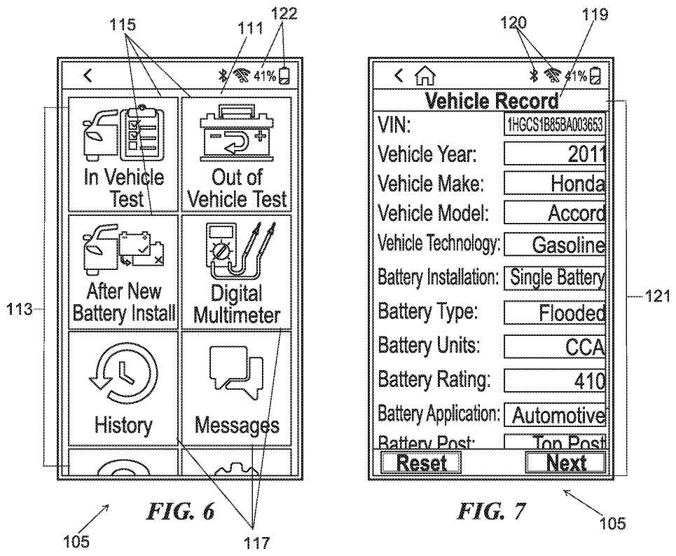

FIG. 6 shows the user interface 105, particularly a menu interface 111, featuring a number of icons 113. In the illustrated example, the icons 113 are arranged in a 2×3 grid, while additional icons 113 may be accessible if a user scrolls down to look and see what is available. However, one of skill in the art would understand that variations thereon may be acceptable for the purposes provided. The icons 113 may be sized for ease of selection by a variety of users. The user interface 105 may be particularly advantageous in dirty conditions, low-light conditions, and the like. The icons 113 may be understood to be pictographic representations of tester functions which are programmed to allow navigation. In other words, a technician or operator of the battery tester may tap the icon to navigate through tester functionality. The icons 113 may guide access to (but are not limited to) testing specific navigation 115 and other tester functionality 117, in various embodiments.

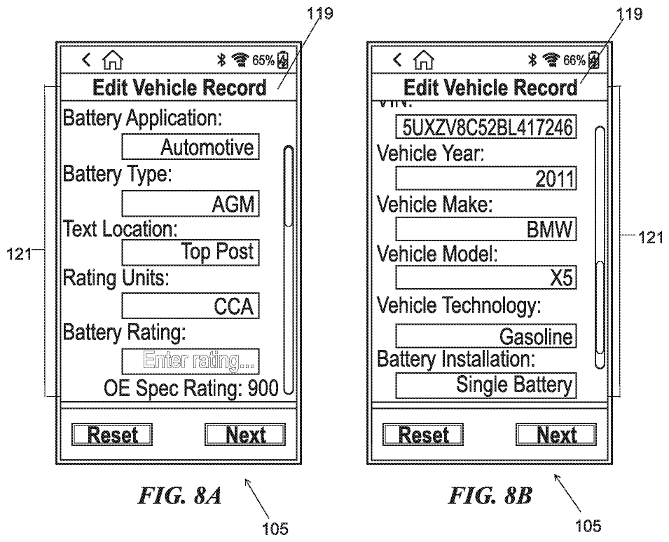

In one example, the icons 113 are used to navigate to the next user interface screen of user interface 105, which may comprise interfaces specific to operation of the battery tester and its functionality. For example, FIGS. 7-17D show a number of user interfaces relating to battery tester functionality. On the top of each user interface screen as shown in FIGS. 7-17D, is a number of icons. The icons, from left to right, may be understood to facilitate the following functionality when selected (tapped) by a user: navigate back, go to the home (icon grid) screen, Bluetooth connection status, wireless connection status and strength (which may, for example, show as disconnected (e.g. FIGS. 6-7) or with an ! next to connection strength (e.g. FIGS. 8A-8B)), and battery charge status (both by percentage and icon visualization (e.g. a cylindrical battery icon having varying “fill” levels)). Some of these indicators may likewise be seen in FIG. 6. In various embodiments, some icons may generally be identified as tester battery status 122 and tester connectivity status 120 indicators.

In FIG. 7, a vehicle record interface 119 of the user interface 105 is shown. Descriptions of the fields to be populated may be seen on a left-hand side of the interface, while the populated field may be seen on a right-hand side. These fields may comprise vehicle attributes 121. The entries may be populated by selection of drop-down options. Alternatively, the entries may be populated by activating onboard tester functionality. Entry fields (vehicle record interface 119) may continue beyond a bottom of the screen, therefore a scroll bar may indicate to the user that further information may be entered, for example, by swiping up on the display to reveal further fields. Touch-interface buttons are provided along the bottom of the user interface to “reset” (clear the fields) or “next” (move forward in the interface). FIGS. 8A and 8B show another user interface 105 having a vehicle records interface 119 for inputting vehicle record information (for example, into vehicle attributes 121), according to various embodiments. The interfaces of FIGS. 7, 8A, and 8B may be used, in various embodiments, where the battery tester is connected to a battery provided in a vehicle.

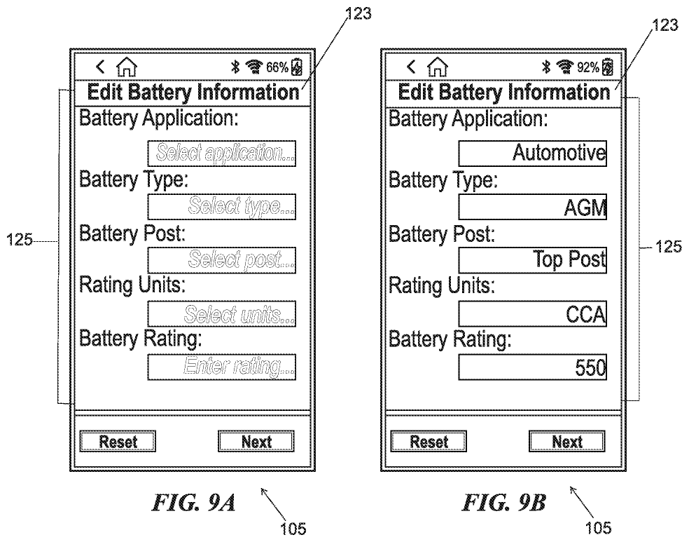

The user interface 105 may further comprise a battery record interface 123. Battery record interface 123 may comprise fields for battery attributes 125. As example embodiments, FIGS. 9A and 9B show a battery record interface 123 for editing battery information. This interface may allow for entry of battery information 125, for example, by selecting the field and tapping a pre-populated option. For example, in FIG. 9A a user may touch the screen where “select application” is filled, and an option for “automotive” may appear in a drop-down manner. Results of selections are shown in FIG. 9B. Again, the user may reset or move forward in the interface 123 by selection of the “reset” or “next” buttons, respectively. This user interface may be encountered, for example, but not limited to, where the tester is used to test a battery outside of a vehicle.

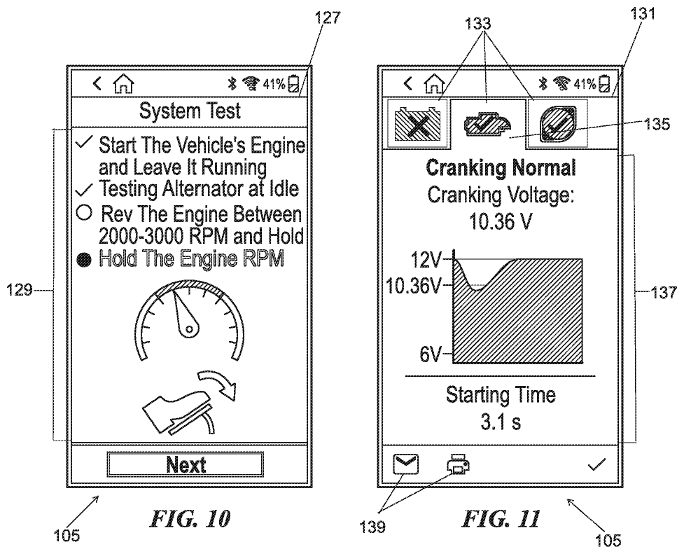

FIG. 10 illustrates a user interface of a battery tester 105 showing a battery or vehicle system testing interface 127. As can be seen, a number of instructions (user instructions 129) are displayed to the operator. The user testing interface 127 may progress through the instructions 129 as the action is performed by the operator. Alternatively, the interface may change display dynamically as the action is performed by the operator. Once the tasks are performed, the user may select “next” to proceed, for example, to testing results.

FIGS. 11-18D show various embodiments of a testing results user interface 131. In the illustrated example, results are given as to three testing metrics (three-stage top navigation 133). Although more or fewer result metrics may be displayed. Along the top of the screen (below the “back,” “home,” “Bluetooth,” “wireless,” and “battery” selections shown), three icons, including a red battery, green engine, and green circle in a leaf may be seen (“three-stage top navigation”) 133. These three icons may allow a user to navigate between results options, as well as obtain a quick overview of battery health metrics. At a bottom of a testing results user interface 131 user output icons 139 may be seen. These may allow for selection of delivery of results information by, for example, email or printing, in various embodiments.

As shown in FIGS. 11, 12, and 13, looking to the top navigation of the three-stage top navigation, a user may immediately ascertain there are issues with, for example, the battery reserve capacity necessitating replacement, but engine cranking and charge may be normal.

FIG. 11 shows a cranking results interface 135 which may include a cranking data display 137. For example, the display 137 may show a graph of results of a cranking test. For example, FIG. 11 results display 137 may show a cranking result having a voltage curve and assessment (this may allow the “engine” icon to display as “green” with a word result below of “Cranking Normal”). A cranking voltage may be seen as well as a voltage test curve. While the icon and interface may be optionally shown in green to reflect a normal cranking result, alternative colors may be used to reflect poorer test results. This may allow for at-a-glance summaries of battery health metrics by way of the top three-icon navigation described above.

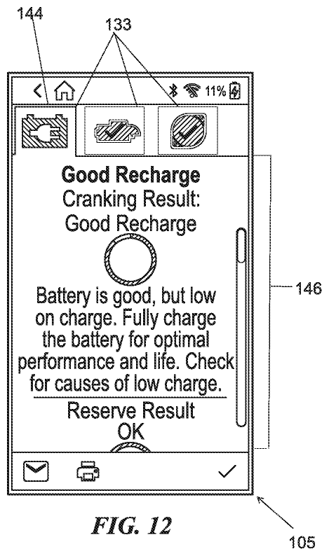

FIG. 12 shows the user interface 105 having a recharge testing results interface 144. The testing results interface 144 may likewise provide results interface data display 146. In various embodiments, the interface display 146 may include the recharge relative to a cranking result which may be visualized as a color (for example, green) and an icon (almost-full ring). A diagnosis may be seen below the ring, with further diagnostic details provided, including reserve result.

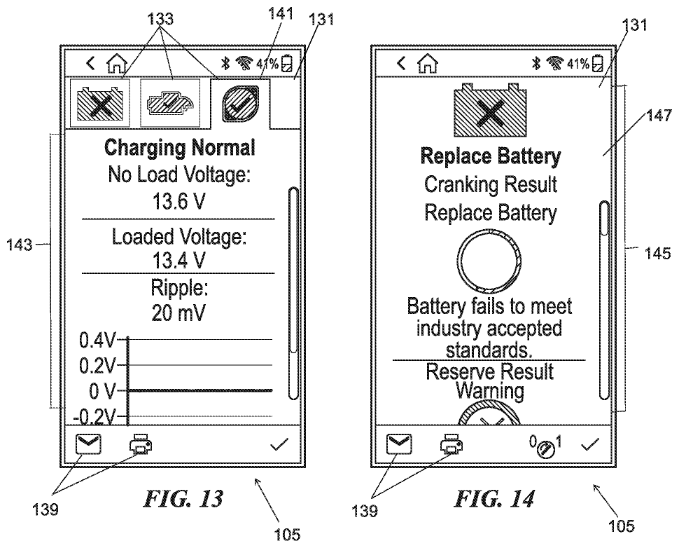

In FIG. 13, the circle in a leaf icon portion of the three-stage top navigation 133 may be selected (note the icon may for example be green and the coloring may be updated to reflect battery health—e.g. if charging is abnormal it may appear red) to display another battery results interface 131 of the battery tester user interface 105. In various embodiments, this interface may be a charging results user interface 141. The charging results user interface 141 may comprise a number of charging results user interface elements 143. The charging test results of FIG. 13 may include a “charging normal” assessment, no load and loaded voltage values, and ripple value, as well as a graph of the test results.

Again, these results may be navigable with minimum effort by the tester by using a three-stage top navigation 133 allowing for easily-accessible information summary. While three icons are used, more or less may be within the scope of this disclosure. In addition, while particular colors (green, red) may be used, others (purple, blue, grey, etc.) should be contemplated as within the scope of this disclosure. In addition, while particular pictographic shapes are used (engine, leaf, ring, battery, etc.) alternatives (squares, other shapes) should be contemplated as within the scope of this disclosure.

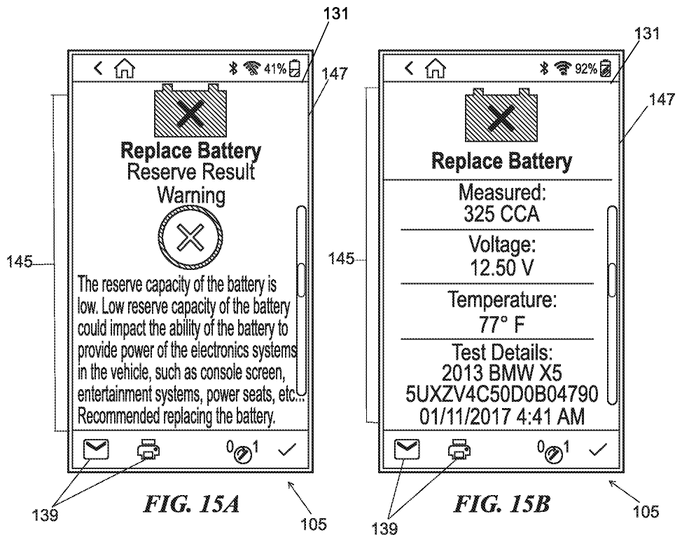

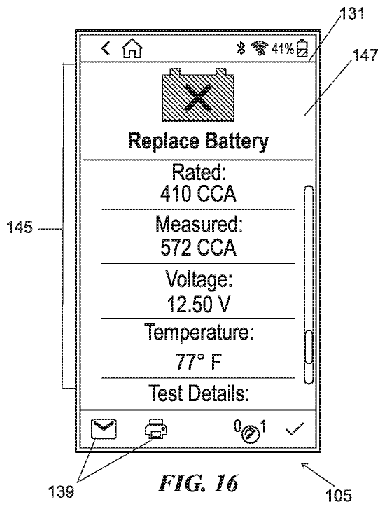

FIG. 14 shows a user results interface 131 summary interface 147 displaying or communicating to a user to replace a battery by way of the a battery health summary display 145. In FIG. 14, the user interface comprises a ring representing battery health. FIGS. 15A-15B illustrate more details regarding information relating to the reserve capacity of the battery. FIG. 16 illustrates a quick reference of information regarding the tested battery and rated metrics on the user interface 105. In each of these interfaces, there may be further information to be obtained by scrolling down (i.e. dragging a user finger from bottom to top of the interface). While scrolling down is described herein, alternative navigation techniques such as side-scrolling may be contemplated as within the scope of this disclosure.

Along the bottom of the user interface 105, for example, in FIGS. 11-18D, a number of icons are visible. These icons may prompt a user to send information such as results via email, to print results, (together, 139) to repeat a test, or to accept the results, according to various examples of embodiments. Various additional or alternative options or fewer options are within the scope of this disclosure.

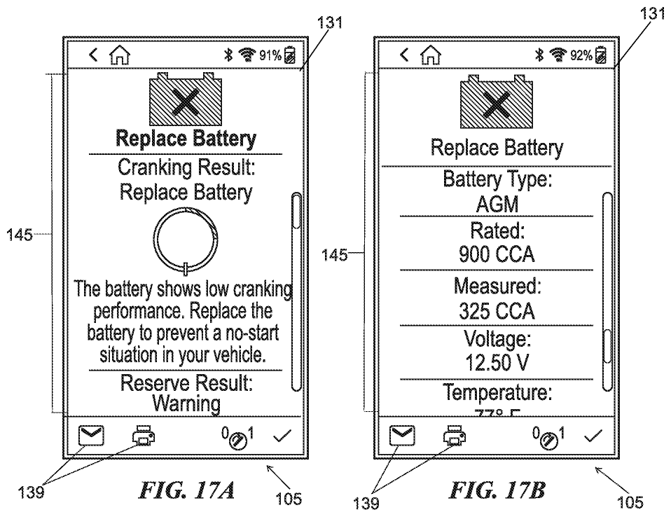

FIGS. 17A and 17B provide two further examples of embodiments of the testing user interface 131 having data interface features 145. FIG. 17A shows a ring visualization of poor cranking results and the recommendation to replace the battery. FIG. 17B shows a visualization of results, base values, and a replacement recommendation as part of the data interface features 143.

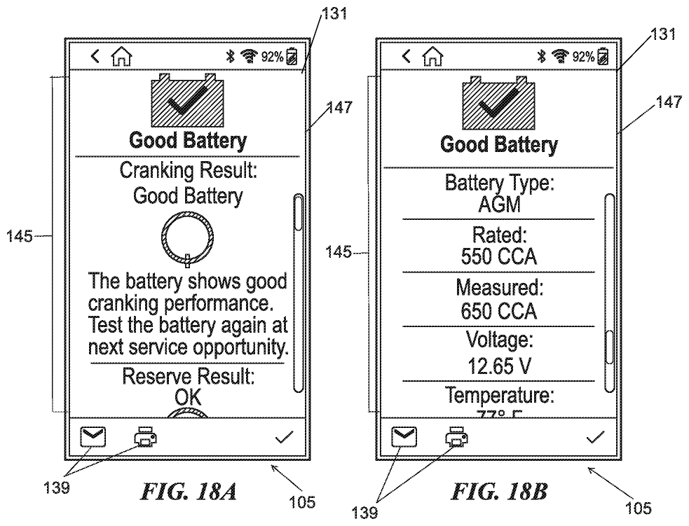

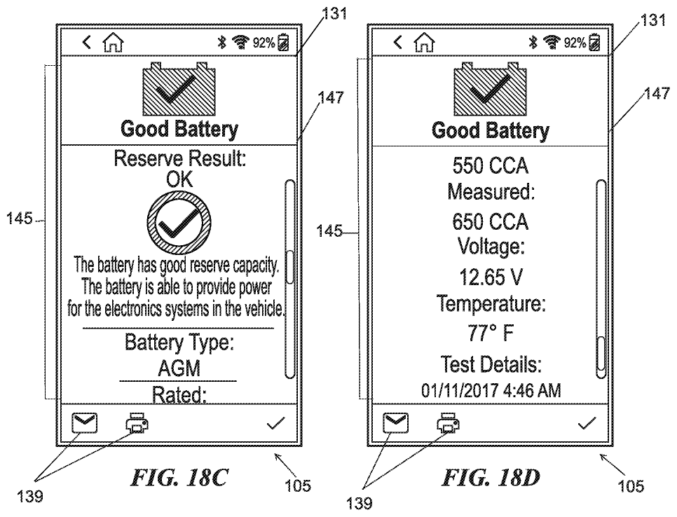

FIGS. 18A through 18D show a number of additional user interface 105 visualizations on battery results user interface 131 results summary interface 147 displaying battery testing results information 145, according to various examples of embodiments. In FIG. 18A a “good battery” cranking result is shown with a ring visualization. Similarly, 18A may be understood to show an “ok” reserve result including a ring visualization. A user may, for example, scroll down to see further results. Similarly, FIG. 18B may be seen to include a “good battery” diagnosis with a battery type, rating, measured amount, voltage, and temperature. Again, the interface 147 may allow for scrolling down to obtain further information 145. FIG. 18C shows a view of a report of a reserve result. A checkmark (which may, in various embodiments, be green) as shown may indicate to the user that the battery has a good reserve capacity. FIG. 18D shows a further view of the scrolled result of FIG. 18B.

FIG. 19 shows a front and back of a battery tester 101 having a screen 103 displaying a user interface 105 according to various examples of embodiments. As stated previously, the battery tester may be held with one hand while the user interface is operated. In addition, a mobile device 106 may be seen.

FIG. 20 shows a workflow for interaction of the user interface, according to various embodiments. First, in step S201, a user may hold the tester in one hand. Then, in step S203, the user may swipe up on the display screen to open the testing application user interface. Next, in step S205, the user interface icon grid may be displayed. Then, in step S207 data entry may be displayed (for example, to populate vehicle information and/or battery information) and/or instructions for testing may be displayed to the user. This step may populate instructions for the testing as shown and described in the example above. Next, in step S209, the results summary may be displayed. The three-part navigation may likewise in alternative embodiments be shown to display different types of testing results. In step S211, the user interface may likewise display transmittal options for sending testing results. In various embodiments, transmittal options may be part of the results interface. In order to navigate the interface, the user may tap, scroll, or otherwise interact with a touch-sensitive display screen provided on the battery tester.

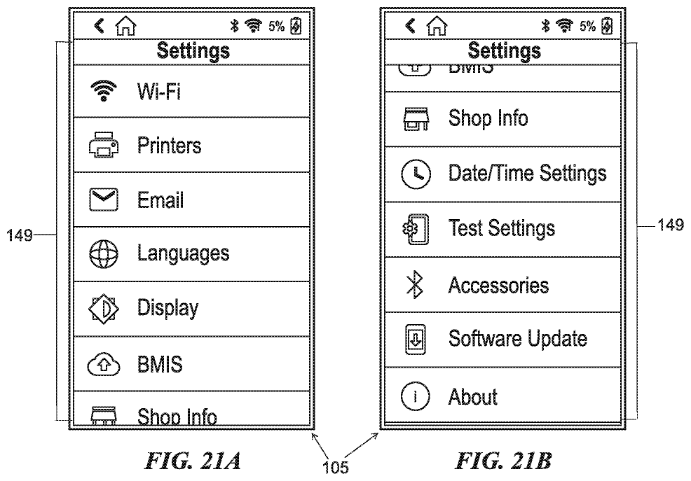

FIGS. 21A and 21B show a user interface 105 featuring settings configuration 149, according to various embodiments. A user may scroll down to see the features of 20B from the interface of 21A. The settings user interface options 149 may include: wireless connection settings, printing, emailing (results transmittal), language (user interface display language), display, battery management information systems (BMIS), shop information, date/time settings, test settings, accessories (including Bluetooth settings), software update, and information about the tester.

The user interface for a battery tester described herein has a number of advantages. For example, the user interface may be navigable while holding the device in one hand. The user interface may be simple to navigate, allowing for quick use during battery testing. The user interface may facilitate the display of a range of testing information without requiring further navigation, printing, and the like.

It should be noted that references to relative positions (e.g., “top” and “bottom”) in this description are merely used to identify various elements as are oriented in the Figures. It should be recognized that the orientation of particular components may vary greatly depending on the application in which they are used.

For the purpose of this disclosure, the term “coupled” means the joining of two members directly or indirectly to one another. Such joining may be stationary in nature or moveable in nature. Such joining may be achieved with the two members or the two members and any additional intermediate members being integrally formed as a single unitary body with one another or with the two members or the two members and any additional intermediate members being attached to one another. Such joining may be permanent in nature or may be removable or releasable in nature.

It is also important to note that the construction and arrangement of the system, methods, and devices as shown in the various examples of embodiments is illustrative only. Although only a few embodiments have been described in detail in this disclosure, those skilled in the art who review this disclosure will readily appreciate that many modifications are possible (e.g., variations in sizes, dimensions, structures, shapes and proportions of the various elements, values of parameters, mounting arrangements, use of materials, colors, orientations, etc.) without materially departing from the novel teachings and advantages of the subject matter recited. For example, elements shown as integrally formed may be constructed of multiple parts or elements show as multiple parts may be integrally formed, the operation of the interfaces may be reversed or otherwise varied, the length or width of the structures and/or members or connector or other elements of the system may be varied, the nature or number of adjustment positions provided between the elements may be varied (e.g. by variations in the number of engagement slots or size of the engagement slots or type of engagement). The order or sequence of any algorithm, process, or method steps may be varied or re-sequenced according to alternative embodiments. Likewise, some algorithm or method steps described may be omitted, and/or other steps added. Other substitutions, modifications, changes and omissions may be made in the design, operating conditions and arrangement of the various examples of embodiments without departing from the spirit or scope of the present inventions.

While this invention has been described in conjunction with the examples of embodiments outlined above, various alternatives, modifications, variations, improvements and/or substantial equivalents, whether known or that are or may be presently foreseen, may become apparent to those having at least ordinary skill in the art. Accordingly, the examples of embodiments of the invention, as set forth above, are intended to be illustrative, not limiting. Various changes may be made without departing from the spirit or scope of the invention. Therefore, the invention is intended to embrace all known or earlier developed alternatives, modifications, variations, improvements and/or substantial equivalents.

The technical effects and technical problems in the specification are exemplary and are not limiting. It should be noted that the embodiments described in the specification may have other technical effects and can solve other technical problems. Aspects of the method described herein are implemented on a software system running on a computer system. To this end, the methods and system may be implemented in, or in association with, a general-purpose software package or a specific purpose software package. As a specific, non-limiting example, the device could be a battery tester having a user interface in communication with a cloud storage database and/or mobile device.

The software system described herein may include a mixture of different source codes. The system or method herein may be operated by computer-executable instructions, such as but not limited to, program modules, executable on a computer. Examples of program modules include, but are not limited to, routines, programs, objects, components, data structures, and the like which perform particular tasks or implement particular instructions. The software system may also be operable for supporting the transfer of information within a network.

While the descriptions may include specific devices or computers, it should be understood the system and/or method may be implemented by any suitable device (or devices) having suitable computational means. This may include programmable special purpose computers or general-purpose computers that execute the system according to the relevant instructions. The computer system or portable electronic device can be an embedded system, a personal computer, notebook computer, server computer, mainframe, networked computer, workstation, handheld computer, as well as now known or future developed mobile devices, such as for example, a personal digital assistant, cell phone, smartphone, tablet computer, mobile scanning device, and the like. Other computer system configurations are also contemplated for use with the communication system including, but not limited to, multiprocessor systems, microprocessor-based or programmable electronics, network personal computers, minicomputers, smart watches, and the like. Preferably, the computing system chosen includes a processor suitable for efficient operation of one or more of the various systems or functions or attributes of the communication system described.

The system or portions thereof may also be linked to a distributed computing environment, where tasks are performed by remote processing devices that are linked through a communication network(s). To this end, the system may be configured or linked to multiple computers in a network including, but not limited to, a local area network, wide area network, wireless network, and the Internet. Therefore, information, content, and data may be transferred within the network or system by wireless means, by hardwire connection, or combinations thereof. Accordingly, the devices described herein communicate according to now known or future developed pathways including, but not limited to, wired, wireless, and fiber-optic channels.

In one or more examples of embodiments, data may be stored remotely (and retrieved by the application) or may be stored locally on a user's device in a suitable storage medium. Data storage may be in volatile or non-volatile memory. Data may be stored in appropriate computer-readable medium including read-only memory, random-access memory, CD-ROM, CD-R, CD-RW, magnetic tapes, flash drives, as well as other optical data storage devices. Data may be stored and transmitted by and within the system in any suitable form. Any source code or other language suitable for accomplishing the desired functions described herein may be acceptable for use.

Furthermore, the computer or computers or portable electronic devices may be operatively or functionally connected to one or more mass storage devices, such as but not limited to, a hosted database or cloud-based storage.

The system may also include computer-readable media which may include any computer-readable media or medium that may be used to carry or store desired program code that may be accessed by a computer. The invention can also be embodied as computer-readable code on a computer-readable medium. To this end, the computer-readable medium may be any data storage device that can store data. The computer-readable medium can also be distributed over a network-coupled computer system so that the computer-readable code is stored and executed in a distributed fashion.

What is claimed is:

1. A battery tester comprising a computing device and a screen, the computing device being configured to display on the screen a user interface for improved battery testing;
the user interface comprising a series of interfaces:
a first interface comprising a plurality of icons, each of the plurality of icons corresponding to at least one of a test condition or a tester functionality;
a testing interface comprising a number of instructions which update based on a user interaction with a vehicle, and wherein selection of an icon in the first interface corresponding to a test condition displays the testing interface; and
a results interface, having a three-stage top navigation and summary, the three-stage top navigation for reporting battery health metrics, wherein completion of the testing interface displays a results interface.

2. The battery tester of claim 1, wherein one or more selections of the three-stage top navigation comprises a cranking result or a charging result.

3. The battery tester of claim 2, wherein selection of one or more selections of the three-stage navigation presents a battery replacement recommendation.

4. The battery tester of claim 1, wherein selection of one or more selections of the three-stage navigation provides a testing results summary interface.

5. The battery tester of claim 4, wherein viewing of the testing results summary interface may be achieved by scrolling downward on the tester user interface.

6. The battery tester of claim 1, further comprising a vehicle record interface, the vehicle record interface having a plurality of fields for inputting vehicle information, wherein the vehicle record interface may be populated by a user or tester-obtained data.

7. The battery tester of claim 1, wherein the battery tester is sized to be held one-handed.

8. The battery tester of claim 1, wherein one selection of the three-stage top navigation comprises a cranking result.

9. The battery tester of claim 1, wherein selection of one or more selections of the three-stage navigation presents a battery replacement recommendation.

10. The battery tester of claim 1, wherein selection of one stage of the three-stage navigation provides a testing results summary interface.

11. A method for improved battery health data capture and display, the method comprising:
holding a battery tester, the battery tester having a screen displaying a user interface;
selecting one of a plurality of icons displayed on the user interface corresponding to a test condition to begin a test;
displaying on the user interface a testing interface which dynamically updates based on the completion of one or more testing steps;
upon completion of one or more tests, displaying on the user interface a results interface having a three-stage navigation and health summary, the three-stage top navigation corresponding to different battery health information;
selecting on the user interface one or more selections of the three-stage top navigation to display a results summary and recommendation regarding battery health.

12. The method of claim 11, further comprising populating on the user interface a vehicle information interface, the vehicle information interface optionally being populated by manual entry.

13. The method of claim 11, wherein the battery tester is sized to be held in one hand.

14. The method of claim 13, wherein the user interface is vertically-oriented.

15. The method of claim 14, wherein the battery tester screen is a touchscreen.

16. A method for displaying battery health information on a graphical user interface, the method comprising:
providing a touchscreen on a battery tester, the touchscreen displaying a user interface;
displaying on the user interface a testing interface which dynamically updates with testing instructions based on the completion of one or more testing steps;
upon completion of one or more tests, displaying on the user interface a results interface having a three-stage navigation and health summary, the three-stage top navigation corresponding to different battery health metrics;
selecting on the user interface one or more selections of the three-stage top navigation to display a testing results summary and recommendation regarding battery health.

17. The method of claim 16, wherein the battery tester is sized to be held in one hand.

18. The method of claim 16, wherein the user interface is vertically-oriented.

19. The method of claim 16, wherein one of the three-stage top navigation comprises a cranking result.
